(19) United States
(12) Patent Application Publication
(10) Pub. No.: US 2016/0283121 A1
(43) Pub. Date: Sep. 29, 2016

(54) NUMERICAL CONTROLLER INCLUDING MAINTENANCE FUNCTION OF DATA OR THE LIKE STORED IN NON-VOLATILE MEMORY

(71) Applicant: FANUC Corporation, Minamitsuru-gun (JP)

(72) Inventor: Norihide SATO, Minamitsuru-gun (JP)

(21) Appl. No.: 15/067,223

(22) Filed: Mar. 11, 2016

(30) Foreign Application Priority Data
Mar. 24, 2015 (JP) 2015-060568

(51) Int. Cl. G06F 3/06; G01R 31/36; G11C 11/419; G06F 11/07; G11C 14/00; G11C 16/10

(52) U.S. Cl. CPC G06F 3/0604; G11C 14/0054; G11C 16/10; G11C 11/419; G06F 3/0659; G06F 3/0679; G06F 11/0727; G06F 11/0751; G06F 11/0787; G06F 11/079; G01R 31/362

(57) ABSTRACT

A numerical controller includes: a non-volatile memory; a first power source that supplies electrical power to the non-volatile memory; a second power source that supplies electrical power wirelessly or by wired connection; and a microcomputer. The microcomputer is provided with power supply from the second power source, and performs reading of data stored in the non-volatile memory and writing of data to the non-volatile memory. Even when the first power source is turned off, power supply from the outside wirelessly or by wired connection becomes possible by use of the second power source.

### BACKGROUND OF THE INVENTION

1. Field of the Invention

The present invention relates to a numerical controller, and in particular, relates to a numerical controller capable of performing maintenance management, such as error check or backup of a non-volatile memory, even when power is off or when a failure occurs.

2. Description of the Related Art

In some non-volatile memories, similar to a battery-backup SRAM, there occurs a soft error (a transient failure, and moreover, a failure not including breakage of hardware, such as a semiconductor or electronic components) under the influence of cosmic rays or the like, or, similar to a NAND flash memory, an accumulated charge is gradually reduced to cause a data error.

In either case, a device can be continuously used by rewriting into correct data before it becomes impossible to carry out error correction by ECC or the like due to accumulation of data errors; however, for detecting the data error early, it is necessary to read data from the non-volatile memory on a regular basis. However, since data in a non-volatile memory usually cannot be read in a power-off state of a device, it is required to perform an operation of turning on the device to start it up. Moreover, there is a problem that, in a state where a device is inoperable or disabled to turn on due to breakdown, data in a non-volatile memory cannot be read as it is.

As a conventional art related to such a problem, for example, in Japanese Patent Application Laid-Open No. 2014-120263, there is disclosed a technique to use a non-contact IC memory and to perform reading and writing from and to the non-contact IC memory by wireless power supply. Moreover, for example, in Japanese Patent Application Laid-Open No. 2013-197805, there is disclosed a technique that enables to use an electronic appliance even when power supply to the electronic appliance is stopped, by switching power supply to the electronic appliance from an emergency battery which is separately prepared.

However, in the technique disclosed in the above-described Japanese Patent Application Laid-Open No. 2014-120263, there is a problem that, even though reading and writing of data from and to the non-contact IC memory is possible without turning on the device, reading and writing of data from and to a device other than the non-contact IC memory is impossible, and therefore, it is impossible to adapt the technique to a system incorporating multiple types of non-volatile memories.

Moreover, in the technique disclosed in the above-described Japanese Patent Application Laid-Open No. 2013-197805, in the case where the device becomes inoperable or the device cannot be turned on due to failure of CPU or the like, the data stored in the non-volatile memory cannot be evacuated; therefore, in the case where a board on which the non-volatile memory is mounted is replaced, the data in the non-volatile memory implemented on the board is lost.

### SUMMARY OF THE INVENTION

An object of the present invention is to provide a numerical controller capable of performing maintenance management, such as error check or backup of a non-volatile memory, even when power is off or when a failure occurs.

A numerical controller according to the present invention includes: a non-volatile memory; a first power source that supplies electrical power to the non-volatile memory; a second power source that supplies electrical power to the non-volatile memory wirelessly or by wired connection; and a microcomputer that is provided with electrical power from the second power source and performs reading of data stored in the non-volatile memory or writing of data to the non-volatile memory.

The numerical controller may be configured to check if any data error does not occur by reading data in the non-volatile memory via the microcomputer on a regular basis, and to predict an encouraged timing for next checking of data in the non-volatile memory based on a time interval in the checking and a data error occurrence status.

The numerical controller may further include an RTC capable of receiving power supply from the first power source, the second power source and a backup battery, and also capable of reading a time and performing time setting via the microcomputer, and time data of the RTC may be corrected by being cross-checked with time data of an external device.

The numerical controller may further include an A/D converter that measures a voltage value of the backup battery, and a voltage of the battery may be measured via the microcomputer, and the voltage of the battery may be checked by comparing the measured voltage of the battery with a predetermined reference voltage.

According to the present invention, even though an operation of turning on a device to start it up is not performed, it is possible to confirm a data error occurrence status in a non-volatile memory incorporated in the device, a battery voltage or an RTC status by an operation from an external device, and in a case where a data error occurs, it is possible to correct the error. Moreover, it is possible to predict a next check timing of data error based on the data error occurrence status and prevent system failure caused by accumulation of data errors.

Further, even in a case where it becomes impossible to operate a device or to turn on the device due to failure, since reading and writing of data from and to the non-volatile memory in the device can be performed from the external device, it is possible to evacuate the data stored in the non-volatile memory, and accordingly, the time required to recover the device can be significantly reduced.

### BRIEF DESCRIPTION OF THE DRAWINGS

FIG. 1 is a block diagram showing main parts of a numerical controller according to an embodiment of the present invention.

### DETAILED DESCRIPTION OF THE PREFERRED EMBODIMENTS

A numerical controller according to the present invention includes a microcomputer that performs communication control with external devices, monitoring of a battery status, and reading and writing of data from and to a non-volatile memory. A power source for supplying electrical power to the microcomputer, the non-volatile memory and an RTC (Real-Time Clock) is separated from a power source for the other circuits, thereby making it possible to operate the microcomputer, the non-volatile memory and the RTC by supplying electrical power from the outside.

Moreover, in a case where an error occurs in data in the non-volatile memory, error correction is performed and details of the performed error correction are recorded in the non-volatile memory. By comparing the recorded information with a status in the next time confirmation, property deterioration of the memory is judged, and thereby an advice on the maintenance period is provided, or a time for replacing a board on which the memory is mounted is determined.

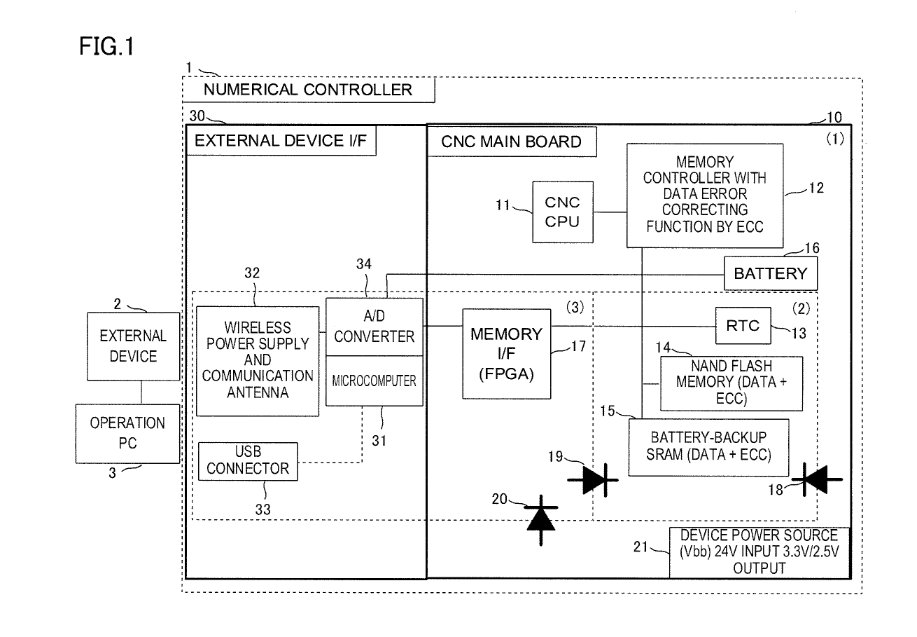

The numerical controller according to an embodiment of the present invention will be described with reference to FIG. 1.

The numerical controller 1 includes a CNC main board 10 and an external device interface 30.

The CNC main board 10 includes: a CNC CPU 11 that controls an entire operation of the numerical controller 1; a memory controller 12 with a data error correcting function by ECC; an RTC (a real time clock circuit) 13 that measures an internal time of the numerical controller 1; a NAND flash memory 14 including an ECC function; an SRAM 15 with battery backup; a battery 16 that supplies electrical power to the RTC 13, the NAND flash memory 14 and the SRAM 15; and further, a non-volatile memory interface 17 that mediates an access to the RTC 13, the NAND flash memory 14 and the SRAM 15.

The external device interface 30 includes: a microcomputer 31 including a short range communication interface or a USB interface; a wireless power supply and communication antenna 32 that is connected to the short range communication interface to perform wireless power supply from the external device 2 and wireless communication; a USB connector 33 that is connected to the USB interface to perform USB power supply from the external device 2 and USB communication; and an A/D converter 34. The external device interface 30 is configured as, for example, an expansion board or a peripheral device, which is connected to the CNC main board 10 in a removable manner via a connector (not shown) or the like, and accordingly, in the event of failure, the external device interface 30 is able to be replaced with another external device interface 30 as needed.

The inside of the numerical controller 1 is divided into three power source areas, namely, a power source area (1), a battery power source area (2) and an external power supply area (3).

The power source area (1) receives power supply from a device power source 21, and in this power source area (1), the CNC CPU 11, the memory controller 12, the battery 16 and the like are arranged. When the device power source 21 is turned on, these components receive the power supply from the device power source 21 and operate, whereas, when the device power source 21 is turned off, power supply to these components is stopped, and these components stop operating. Moreover, while the device power source 21 is on, the battery 16 is charged by electrical power supplied from the device power source 21.

The battery power source area (2) receives power supply from the device power source 21 via the power supply circuit 18 to operate in the case where the device power source 21 is on, whereas, in the case where the device power source 21 is turned off, the battery power source area (2) receives power supply from the battery 16, or the external power supply area (3) via the power supply circuit 19 to operate. By receiving power supply from the battery 16, the RTC 13 and the SRAM 15 arranged in the battery power source area (2) are able to retain the present time or stored data even when the device power source 21 is turned off.

The external power supply area (3) receives power supply from the device power source 21 via the power supply circuit 20 to operate in the case where the device power source 21 is on, whereas, in the case where the device power source 21 is turned off, the external power supply area (3) receives power supply from the wireless power supply and communication antenna 32, or receives electrical power from the outside via the USB connector 33 to operate.

In this manner, in the case where the device power source 21 is on, all of the three power source areas are provided with electrical power from the device power source 21 to operate, whereas, in the case where the device power source 21 is off, the battery power source area (2) receives electrical power from the battery 16, but the power source area (1) and the external power supply area (3) are not provided with electrical power from the battery 16. Moreover, when receiving remote power supply from the external device 2 via the wireless power supply and communication antenna 32, or receiving USB power supply from the external device 2 via the USB connector 33, the external power supply area (3) and the battery power source area (2) are provided with power supply to operate.

The operation of the numerical controller 1 with such a configuration will be divided in some operating situations to be described as follows.

### I: Access to Microcomputer, Non-volatile Memory and RTC from External Device

If the external device 2 including the wireless power supply function and the wireless communication function is brought near to the wireless power supply and communication antenna 32 (or, if the external device 2 is connected to the USB connector 33 by use of a USB cable), power supply from the external device 2 via the wireless power supply and communication antenna 32 (or, power supply via the USB connector 33) is performed, and thereby the external power supply area (3) and the battery power source area (2) are provided with electrical power, thereby enabling each device in the external power supply area (3) and the battery power source area (2) to operate.

In such a situation, if a user operates the operation PC 3 connected to the external device 2 and provides instructions to the microcomputer 31 via the external device 2 and the wireless power supply and communication antenna 32, the microcomputer 31 reads and writes data from and to the non-volatile memories (the NAND flash memory 14 and the SRAM 15). Accordingly, data error occurrence status can be confirmed by reading data from these non-volatile memories.

Similarly, by operating the operation PC 3 to provide instructions to the microcomputer 31 by the user, it is possible to conduct A/D conversion of voltage of the battery 16 by the A/D converter 34 and to measure the voltage value. By comparing a measured value obtained as a result of the measurement with a predetermined reference value, it is possible to confirm whether or not the battery 16 outputs a voltage sufficient to back up the SRAM 15 or the RTC 13.

Moreover, the user can read the time data from the RTC 13 by operating the operation PC 3 and providing instructions to the microcomputer 31. Then, it is possible to confirm whether or not the time data in the RTC 13 is correct by comparing the time data with the time of the PC.

Further, since it becomes possible to access the non-volatile memories (the NAND flash memory 14 and the SRAM 15) without using the device power source 21 or the CNC CPU 11, even when the numerical controller 1 cannot be operated for a reason of failure in the power source circuits related to the CNC CPU 11 and the device power source 21 or the like, it becomes possible to evacuate the data in the non-volatile memories, and accordingly, the time required to recover the numerical controller 1 can be significantly reduced by restoring the data after the faulty board is replaced.

### II: Check and Correction of Data in Non-volatile Memory

With respect to the non-volatile memory, such as the NAND flash memory 14 or the backup SRAM 15, a tendency to increase data errors with time is measured in advance in designing and evaluating the numerical controller 1, and incorporated into a program of the device as approximation function data.

When the numerical controller 1 is normally operated, reading of data from the non-volatile memory, such as the NAND flash memory 14 or the backup SRAM 15, is carried out by the CNC CPU 11 as necessary, and when the reading is carried out, the memory controller 12 performs detection and correction of data errors. Moreover, the data in all regions of the non-volatile memory, such as the NAND flash memory 14 or the backup SRAM 15, is read on a regular basis and detection and correction of the data errors are carried out. As a result, if any data error occurs, the location of occurrence of the data error, the number of error bits, and the time and date of checking are recorded in an error information storage region provided in the non-volatile memory.

Then, the data is checked, and if any data error occurs, the information recorded in the error information storage region is read. Based on the data error occurrence status confirmed last time and the confirmation cycle, the timing at which the data errors reach the uncorrectable number of errors (that differs depending on an ECC configuration) is predicted, and thereby, the regular confirmation cycle is corrected. For example, such adjustment of the confirmation cycle as described below is possible; in a case where an initial value of the confirmation cycle is set to one year and data in all regions of the non-volatile memory is confirmed once in a year, if 1-bit error occurs at 3 locations in the non-volatile memory in given one year, it is determined that there is a possibility of evolving into 3-bit error in one year and the confirmation cycle (of which the initial value is one year) is changed to ⅓, whereas, if there occurs no error, confirmation is continued by the predetermined confirmation cycle.

When check and correction of data in the non-volatile memory, such as the NAND flash memory 14 or the backup SRAM 15, is performed by power supply from the external device 2, instructions are provided from the operation PC 3 to the microcomputer 31, and reading of data in all regions of the non-volatile memory, such as the NAND flash memory 14 or the backup SRAM 15, is carried out via the microcomputer 31, to thereby confirm the presence or absence of the data errors. In a case where data error occurs in the non-volatile memory, the memory interface 17, microcomputer 31, or the operation PC 3 carries out the error correction.

Further, an error occurrence location, the number of error bits, and the like are recorded in the error information storage region provided in the non-volatile memory. The operation PC predicts the timing at which the data errors reach the uncorrectable number of errors based on the status of the last time confirmation and the elapsed time, and notifies an operator of the next confirmation timing. Moreover, in a case where the period of time up to the next confirmation is shorter than the predetermined reference value, it may be determined that the memory is at the end of its life, and the operator may be encouraged to replace the board on which the memory is mounted.

The description of an embodiment according to the present invention has been provided above; however, the present invention is not limited to the above-described example of embodiment, and is able to be practiced in various modes by making appropriate modifications.

1. A numerical controller including a non-volatile memory, comprising:
a first power source that supplies electrical power to the non-volatile memory;
a second power source that supplies electrical power to the non-volatile memory wirelessly or by wired connection; and
a microcomputer that is provided with electrical power from the second power source and performs reading of data stored in the non-volatile memory or writing of data to the non-volatile memory.

2. The numerical controller according to claim 1, wherein the numerical controller is configured to check if any data error does not occur by reading data in the non-volatile memory via the microcomputer on a regular basis, and to predict an encouraged timing for next checking of data in the non-volatile memory based on a time interval in the checking and a data error occurrence status.

3. The numerical controller according to claim 1, further comprising an RTC capable of receiving power supply from the first power source, the second power source and a backup battery, and also capable of reading a time and performing time setting via the microcomputer, wherein time data of the RTC is corrected by being cross-checked with time data of an external device.

4. The numerical controller according to claim 3, further comprising an A/D converter that measures a voltage value of the backup battery,
wherein a voltage of the battery is measured via the microcomputer, and the voltage of the battery is checked by comparing the measured voltage of the battery with a predetermined reference voltage.
